(19) United States
(12) Patent Application Publication
(10) Pub. No.: US 2025/0174441 A1
(43) Pub. Date: May 29, 2025

(54) Substrate Processing Apparatus

(71) Applicant: Tokyo Electron Limited, Tokyo (JP)

(72) Inventors: Naoya FUKUDA, Fuchu City (JP); Motoi YAMAGATA, Fuchu City (JP); Hiroshi SONE, Fuchu City (JP)

(21) Appl. No.: 18/950,748

(22) Filed: Nov. 18, 2024

(30) Foreign Application Priority Data
Nov. 28, 2023 (JP) 2023-200868

(51) Int. Cl. H01J 37/32

(52) U.S. Cl. CPC H01J 37/32724; H01J 2237/002; H01J 2237/2007; H01J 2237/20214

(57) ABSTRACT

There is a substrate processing apparatus comprising: a processing chamber; a placing table disposed in the processing chamber and having a first contact surface, the placing table being configured to be rotatable; a freezing device having a second contact surface and configured to be raised and lowered; a rotation device configured to rotate the placing table; and a lifting device configured to raise and lower the freezing device to thermally connect or separate the second contact surface and the first contact surface. The freezing device includes: a refrigerator; a cold link having one end thermally connected to the refrigerator and the other end having the second contact surface, wherein a volume of the cold link is greater than a volume of the placing table.

### CROSS-REFERENCE TO RELATED APPLICATIONS

This application claims priority to Japanese Patent Application No. 2023-200868 filed on Nov. 28, 2023, the entire contents of which are incorporated herein by reference.

### TECHNICAL FIELD The present disclosure relates to a substrate processing apparatus.

### BACKGROUND

Japanese Patent Publication No. 6559347 discloses a holding device for rotatably holding a target object in a vacuum chamber while cooling the target object, the holding device including a stage on which the target object is placed, a rotation driving device for rotatably supporting the stage, and a cooling device for cooling the stage. The rotation driving device includes a cylindrical rotation shaft that is inserted through the wall of the vacuum chamber via a first vacuum seal in a state where the stage surface side on which the target object is placed faces upward, a connecting member that connects the upper end of the rotation shaft to the bottom surface of the stage to define a space below the stage, and a driving motor that rotates and drives the rotation shaft. The cooling device includes a cooling panel that is disposed to face the bottom surface of the stage with a gap interposed therebetween in the space below the stage, a heat transfer shaft that is inserted into the rotation shaft and is brought into contact with the bottom surface of the cooling panel, and a refrigerator that cools the heat transfer shaft.

### SUMMARY

One aspect of the present disclosure provides a substrate processing apparatus that improves cooling performance.

In accordance with an exemplary embodiment of the present disclosure, there is a substrate processing apparatus comprising: a processing chamber; a placing table disposed in the processing chamber and having a first contact surface, the placing table being configured to be rotatable; a freezing device having a second contact surface and configured to be raised and lowered; a rotation device configured to rotate the placing table; and a lifting device configured to raise and lower the freezing device to thermally connect or separate the second contact surface and the first contact surface, wherein the freezing device includes: a refrigerator; a cold link having one end thermally connected to the refrigerator and the other end having the second contact surface, wherein a volume of the cold link is greater than a volume of the placing table.

### BRIEF DESCRIPTION OF THE DRAWINGS

FIG. 1 is a cross-sectional view showing an example of a configuration of a substrate processing apparatus according to an embodiment during rotation of a placing table.

FIGS. 2A and 2B are partially enlarged cross-sectional views showing an example of the configuration during the rotation of the placing table and the cooling of the placing table.

FIG. 3 shows an example of a perspective view of the placing table.

FIG. 4 shows an example of a schematic diagram explaining a structure for supplying a power to a chuck electrode.

FIG. 5 shows an example of a schematic cross-sectional view of an electrode introducing part.

### DETAILED DESCRIPTION

Hereinafter, embodiments of the present disclosure will be described in detail with reference to the accompanying drawings. Like reference numerals will be given to like parts throughout the drawings, and redundant description thereof may be omitted.

In this specification, directions such as parallel, right-angled, orthogonal, horizontal, vertical, up and down, and left and right are allowed to deviate without spoiling the effect of the embodiment. The shape of a corner is not limited to a right angle and may be rounded in an arch shape. The terms parallel, right-angled, orthogonal, horizontal, vertical, circular, and equal may include substantially parallel, substantially right-angled, substantially orthogonal, substantially horizontal, substantially vertical, substantially circular, and substantially equal, respectively.

### <Substrate Processing Apparatus>

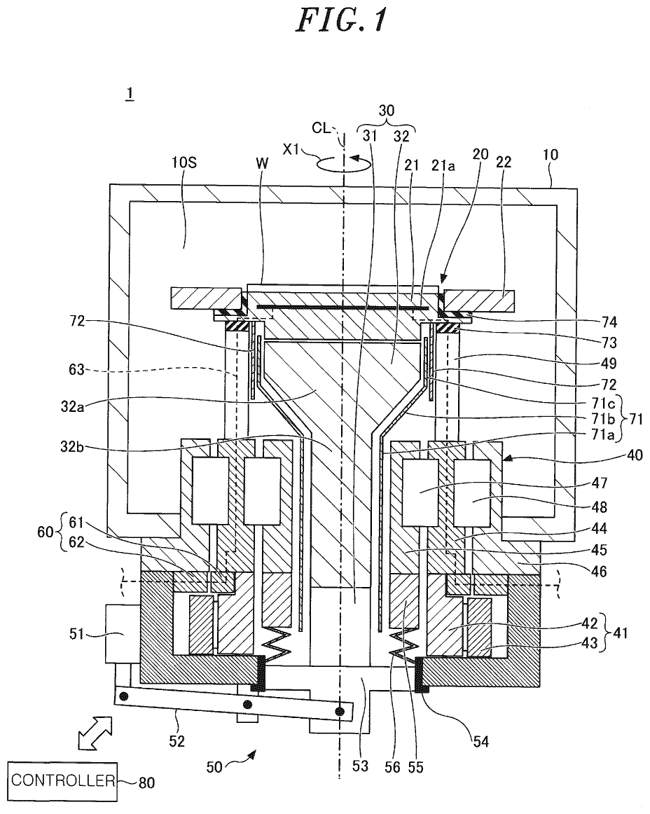

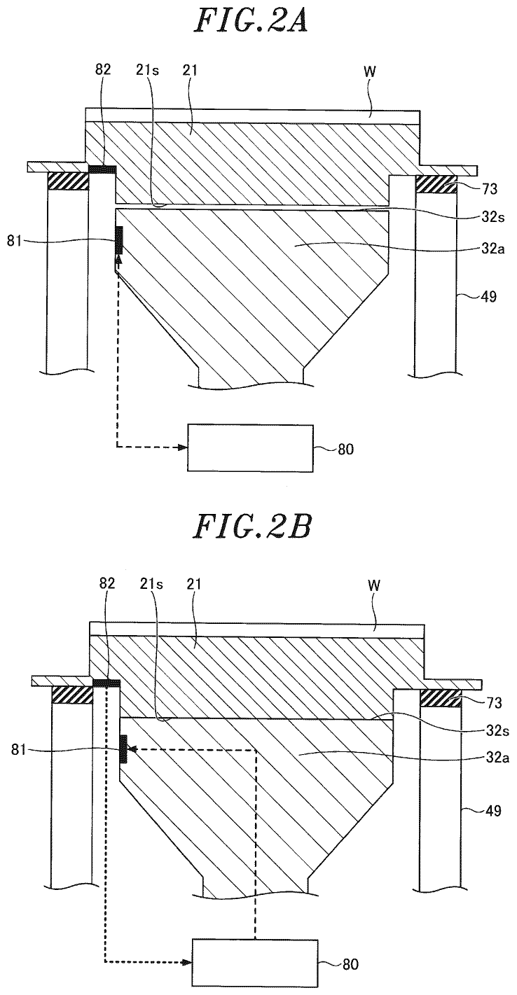

An example of a substrate processing apparatus 1 according to an embodiment will be described with reference to FIGS. 1, 2A and 2B. FIG. 1 is a cross-sectional view showing an example of a configuration of the substrate processing apparatus 1 according to an embodiment during rotation of a placing table 20. FIGS. 2A and 2B are partially enlarged cross-sectional view showing an example of the configuration during the rotation of the placing table 20 and the cooling of the placing table 20. FIG. 2A shows the placing table 20 during the rotation thereof, and FIG. 2B shows the placing table 20 during cooling thereof.

The substrate processing apparatus 1 may be, e.g., a chemical vapor deposition (CVD) apparatus or an atomic layer deposition (ALD) apparatus that supplies a processing gas into a processing chamber 10 and performs desired processing (such as film formation or the like) on a substrate W. The substrate processing apparatus 1 may also be, e.g., a plasma-enhanced chemical vapor deposition (PE-CVD) apparatus or a plasma-enhanced atomic layer deposition (PE-ALD) apparatus that generates plasma of a processing gas in the processing chamber 10 and performs desired processing on the substrate W. The substrate processing apparatus 1 may be, e.g., a physical vapor deposition (PVD) apparatus that supplies a processing gas into the processing chamber 10 and sputters a target disposed in the processing chamber 10 to perform desired processing (such as film formation or the like) on the substrate W.

The substrate processing apparatus 1 includes the processing chamber 10, the placing table 20 on which the substrate W is placed in the processing chamber 10, a freezing device 30, a rotation device 40 for rotating the placing table 20, and a lifting device 50 for raising and lowering the freezing device 30. The placing table 20 on which the substrate W is placed is disposed in the processing chamber 10. The substrate processing apparatus 1 further includes a controller 80 for controlling various devices such as the freezing device 30, the rotation device 40, and the lifting device 50.

The processing chamber 10 forms an inner space 10S. The processing chamber 10 is configured such that a pressure in the inner space 10S is reduced to an ultra-high vacuum by operating an exhaust device (not shown) such as a vacuum pump or the like. Further, a desired gas used for substrate processing is supplied into the processing chamber 10 through a gas supply line (not shown) communicating with a gas supply part (not shown).

The placing table 20 is made of a material with high thermal conductivity (e.g., Cu). The placing table 20 includes an electrostatic chuck 21. The electrostatic chuck 21 has a chuck electrode 21a embedded in a dielectric film. The substrate processing apparatus 1 includes a slip ring 60 for supplying a power to the chuck electrode 21a of the rotating placing table 20. A predetermined potential is applied to the chuck electrode 21a via the slip ring 60 and a wiring 63. With this configuration, the substrate W can be attracted and held on the placing surface by the electrostatic chuck 21, and the substrate W can be fixed to the upper surface (placing surface) of the placing table 20. Further, the placing table 20 has a first contact surface 21s (see FIG. 2) that is brought into contact with a refrigeration medium 32 on the surface (bottom surface) opposite to the placing surface (upper surface) on which the substrate W is placed. The first contact surface 21s is, e.g., a flat surface.

Further, a shield member 22 is disposed on a radially outer side of the electrostatic chuck 21 to prevent a film from being adhered to the rotation device 40 or the like when film formation is performed on the substrate W placed on the placing table 20. The shield member 22 is a ring-shaped member and is supported by the electrostatic chuck 21 via a heat insulating member 74 to be described later. In other words, the shield member 22 rotates together with the placing table 20 by the rotation device 40.

Here, the shield member 22 is formed to cover a structure disposed below the placing table 20, such as the rotation device 40 or the like, from the processing gas and the plasma of the processing gas. Alternatively, the shield member 22 is formed to cover the structure disposed below the placing table 20, such as the rotation device 40 or the like, when viewed from a target that emits sputter particles. Therefore, the shield member 22 is formed to have a large surface area, and a temperature is easily increased by the input of radiant heat from the target, the sidewall of the processing chamber 10, or the like.

A heat insulating member 74 is disposed between the placing table 20 (the electrostatic chuck 21) and the shield member 22. The heat insulating member 74 may be made of a resin material with low thermal conductivity (e.g., polytetrafluoroethylene (PTFE) or the like). Accordingly, it is possible to suppress heat from moving from the shield member 22 to the placing table 20 and improve the cooling performance of the placing table 20.

Further, although the case in which the heat insulating member 74 is disposed between the placing table 20 (the electrostatic chuck 21) and the shield member 22 has been described, the present disclosure is not limited thereto. A heat insulating structure that suppresses heat conduction between the placing table 20 (the electrostatic chuck 21) and the shield member 22 may be disposed between the placing table 20 (the electrostatic chuck 21) and the shield member 22. For example, the placing table 20 and the shield member 22 may be in point contact using a pin, rather than surface contact, thereby reducing the contact area and suppressing heat conduction.

The freezing device 30 is configured to be in contact with or separated from the bottom surface of the placing table 20, and cool the placing table 20 (the electrostatic chuck 21). The freezing device 30 is formed by stacking a refrigerator 31 and the refrigeration medium 32. The refrigeration medium 32 can also be referred to as “cold link.” The refrigerator 31 holds the refrigeration medium 32 and cools the upper surface of the refrigeration medium 32 to an extremely low temperature. The refrigerator 31 preferably uses a Gifford-McMahon (GM) cycle in view of cooling performance. One end (lower side) of the refrigeration medium 32 is fixed on the refrigerator 31 and thermally connected thereto, and the upper portion thereof is accommodated in the processing chamber 10. The other end (upper side) of the refrigeration medium 32 has a second contact surface 32s. The refrigeration medium 32 is made of a material having high thermal conductivity (e.g., Cu) or the like, and has a substantially cylindrical outer shape. The refrigeration medium 32 is disposed such that the center thereof coincides with a center axis CL of the placing table 20.

The refrigeration medium 32 has a head portion 32a and a shaft portion 32b. The head portion 32a is a portion having the second contact surface 32s (see FIG. 2) to be in contact with the first contact surface 21s of the placing table 20, and is a portion that expands in a radial direction compared to the shaft portion 32b. The shaft portion 32b is a portion that thermally connects the head portion 32a and the refrigerator 31.

Here, the placing table 20 and the refrigeration medium 32 are made of a material having high thermal conductivity (e.g., Cu). It is preferable that the volume of the refrigeration medium 32 is greater than the volume of the placing table 20. It is also preferable that the heat capacity of the refrigeration medium 32 is greater than the heat capacity of the placing table 20. Accordingly, it is possible to ensure a large heat capacity of the refrigeration medium 32, thereby suppressing a temperature changes in the refrigeration medium 32 due to radiation heat from the sidewall of the treatment chamber 10 or heat transfer from the placing table 20 to the refrigeration medium 32 in the case where the refrigeration medium 32 is brought into contact with the placing table 20.

Further, it is preferable that the volume of the head portion 32a of the refrigeration medium 32 is greater than the volume of the shaft portion 32b of the refrigeration medium 32. Further, it is preferable that the heat capacity of the head portion 32a of the refrigeration medium 32 is greater than the heat capacity of the shaft portion 32b of the refrigeration medium 32. Accordingly, it is possible to ensure a large heat capacity of the head portion 32a of the refrigeration medium 32 to be in contact with the placing table 20, thereby suppressing a temperature change in the refrigeration medium 32 due to radiation heat from the sidewall of the treatment chamber 10 or heat transfer from the placing table 20 to the refrigeration medium 32 in the case where the refrigeration medium 32 is brought into contact with the placing table 20.

Further, it is preferable that the volume of the head portion 32a of the refrigeration medium 32 is greater than the volume of the placing table 20. It is also preferable that the heat capacity of the head portion 32a of the refrigeration medium 32 is greater than the heat capacity of the placing table 20. Accordingly, it is possible to ensure a large heat capacity of the head portion 32a of the refrigeration medium 32 to be in contact with the placing table 20, thereby suppressing a temperature change in the refrigeration medium 32 due to radiant heat from the sidewall of the treatment chamber 10 or heat transfer from the placing table 20 to the refrigeration medium 32 in the case where the refrigeration medium 32 is brought into contact with the placing table 20.

A first reflecting member 71 is disposed around the refrigeration medium 32. The first reflecting member 71 reflects radiant heat from the sidewall of the processing chamber 10 to prevent radiant heat from entering the refrigeration medium 32. The first reflecting member 71 is made of a metal material such as stainless steel (SUS), aluminum, or the like. The surface of the first reflecting member 71 is mirror-finished to reflect radiant heat from the sidewall of the processing chamber 10. Further, the surface of the first reflecting member 71 may be plated (e.g., gold-plated, nickel-plated, or the like). Further, the surface of the refrigerator 31 or the refrigeration medium 32 is plated (e.g., nickel-plated, or the like) to reflect radiant heat. Accordingly, the increase in the temperature of the refrigeration medium 32 due to radiant heat is suppressed, thereby improving the cooling performance of the placing table 20.

The first reflecting member 71 has a cylindrical portion 71a that covers the lateral portions of the refrigerator 31 and the shaft portion 32b, an annular portion 71b that covers the lower part of the head portion 32a, and a cylindrical portion 71c that covers the lateral portion of the head portion 32a. The annular portion 71b may be connected to the cylindrical portion 71a on the inner diameter side, and may be connected to the cylindrical portion 71c on the outer diameter side. Further, the cylindrical portion 71a, the annular portion 71b, and the cylindrical portion 71c may be configured as separate components.

The first reflecting member 71 may be fixed to the processing chamber 10, or may be supported by a freezing device support 53 to be raised and lowered together with the freezing device 30 by the lifting device 50.

The placing table 20 is rotatably supported by the rotation device 40. The rotation device 40 has a rotation driving device 41, a fixed shaft 45, a rotation shaft 44, a housing 46, magnetic fluid seals 47 and 48, and a stand 49. The rotation driving device 41 is a direct drive motor having a rotor 42 and a stator 43. The rotor 42 has a substantially cylindrical shape extending coaxially with the rotation shaft 44, and is fixed to the rotation shaft 44. The stator 43 has a substantially cylindrical shape with an inner diameter larger than the outer diameter of the rotor 42. The rotation driving device 41 may be in a form other than a direct drive motor, and may be in a form including a servomotor and a transmission belt.

The rotation shaft 44 has a substantially cylindrical shape that extends coaxially with the center axis CL of the placing table 20. The fixed shaft 45 is provided inside the rotation shaft 44 in a radial direction. The fixed shaft 45 has a substantially cylindrical shape extending coaxially with the center axis CL of the placing table 20. The housing 46 is provided outside the rotation shaft 44 in a radial direction. The housing 46 has a substantially cylindrical shape extending coaxially with the center axis CL of the placing table 20, and is fixed to the processing chamber 10.

The magnetic fluid seal 47 is provided between the outer peripheral surface of the fixed shaft 45 and the inner circumference of the rotation shaft 44. The magnetic fluid seal 47 rotatably supports the rotation shaft 44 with respect to the fixed shaft 45, and seals the gap between the outer peripheral surface of the fixed shaft 45 and the inner circumference of the rotation shaft 44 to separate the inner space 10S of the decompressible processing chamber 10 from the outer space of the processing chamber 10. The magnetic fluid seal 48 is provided between the inner peripheral surface of the housing 46 and the outer circumference of the rotation shaft 44. The magnetic fluid seal 48 rotatably supports the rotation shaft 44 with respect to the housing 46, and seals the gap between the inner peripheral surface of the housing 46 and the outer circumference of the rotation shaft 44 to separate the inner space 10S of the decompressible processing chamber 10 from the outer space of the processing chamber 10. Accordingly, the rotation shaft 44 is rotatably supported by the fixed shaft 45 and the housing 46. Further, the refrigeration medium 32 is inserted into the radially inner side of the fixed shaft 45. Further, the first reflecting member 71 (the cylindrical portion 71a) having a substantially cylindrical shape is disposed between the fixed shaft 45 and the refrigeration medium 32.

The stand 49 is provided vertically between the rotation shaft 44 and the placing table 20, and is configured to transmit the rotation of the rotation shaft 44 to the placing table 20.

The heat insulating member 73 is disposed between the placing table 20 (the electrostatic chuck 21) and the stand 49. The heat insulating member 73 may be made of a resin material having low thermal conductivity (e.g., PTFE, or the like). Accordingly, it is possible to suppress the heat from moving from the stand 49 to the placing table 20, and improve the cooling performance of the placing table 20.

Although the case in which the heat insulating member 73 is disposed between the placing table 20 (the electrostatic chuck 21) and the stand 49 has been described, the present disclosure is not limited thereto. A heat insulating structure that suppresses heat conduction between the placing table 20 and the stand 49 may be provided between the placing table 20 (the electrostatic chuck 21) and the stand 49. For example, the placing table 20 and the stand 49 may be in point contact using a pin, rather than surface contact, thereby reducing the contact area and suppressing heat conduction.

A substantially cylindrical second reflecting member 72 is provided on the inner peripheral side of the stand 49. The second reflecting member 72 reflects radiant heat from the sidewall of the processing chamber 10 and prevents the radiant heat from entering the refrigeration medium 32. In particular, the upper surface of the head portion 32a of the refrigeration medium 32 serves as the second contact surface 32s to be in contact with the placing table 20, and is not covered by the first reflecting member 71. The second reflecting member 72 prevents radiant heat from the sidewall of the processing chamber 10 or the like from entering the second contact surface 32s of the refrigeration medium 32. Further, the second reflecting member 72 suppresses the radiation heat from entering from the bottom surface of the placing table 20. The second reflecting member 72 is made of a metal material such as stainless steel (SUS), aluminum, or the like. The surface of the second reflecting member 72 is mirror-finished. Further, the surface of the second reflecting member 72 may be plated (e.g., gold-plated, nickel-plated, or the like). Accordingly, the increase in the temperature of the refrigeration medium 32 due to radiation heat is suppressed, thereby improving the cooling performance of the placing table 20.

Further, the second reflecting member 72 may be fixed to the placing table 20 and/or the stand 49, and may be supported by the rotation device 40 to rotate together with the placing table 20. As shown in FIG. 1, the diameter of the second reflecting member 72 may be greater than the diameter of the cylindrical portion 71c of the first reflecting member 71, and at least a part of the first reflecting member 71 may be inserted into the cylindrical second reflecting member 72.

With the above configuration, when the rotor 42 of the rotation driving device 41 rotates, the rotation shaft 44, the stand 49, and the placing table 20 rotate in a X1 direction (see FIG. 1) relative to the refrigeration medium 32.

Further, the freezing device 30 is supported by the lifting device 50 to be vertically movable. The lifting device 50 has an air cylinder 51, a link mechanism 52, the freezing device support 53, a linear guide 54, a fixed portion 55, and a bellows 56.

The air cylinder 51 is a mechanical device whose rod moves linearly by air pressure. The link mechanism 52 converts the linear movement of the rod of the air cylinder 51 into vertical motion of the freezing device support 53. Further, the link mechanism 52 has a lever structure, one end of which is connected to the air cylinder 51 and the other end of which is connected to the freezing device support 53. Accordingly, a large pressing force can be generated with a small thrust of the air cylinder 51. The freezing device support 53 supports the freezing device 30 (the refrigerator 31 and the refrigeration medium 32). The freezing device support 53 is guided in the vertical direction by the linear guide 54.

The fixed portion 55 is fixed to the bottom surface of the fixed shaft 45. The substantially cylindrical bellows 56 surrounding the refrigerator 31 is provided between the bottom surface of the fixed portion 55 and the upper surface of the freezing device support 53. The bellows 56 is a metal bellows structure that is vertically extensible/contractible. Accordingly, the fixed portion 55, the bellows 56, and the freezing device support 53 seal the gap between the inner peripheral surface of the fixed shaft 45 and the outer circumference of the refrigeration medium 32 to separate the inner space 10s of the decompressible processing chamber 10 from the outer space of the processing chamber 10. Further, the bottom surface side of the freezing device support 53 is adjacent to the outer space of the processing chamber 10, and the region surrounded by the bellows 56 on the upper surface side of the freezing device support 53 is adjacent to the inner space 10S of the processing chamber 10.

The substrate processing apparatus 1 includes a slip ring 60 made of a metal and disposed below the rotation shaft 44 and the housing 46 to supply a direct current voltage (DC voltage) to the chuck electrode 21a.

The slip ring 60 includes a rotating body 61 having a metal ring, and a fixed body 62 having a brush. The rotating body 61 has a substantially cylindrical shape extending coaxially with the rotation shaft 44, and is fixed to the bottom surface of the rotation shaft 44. The fixed body 62 has a substantially cylindrical shape with an inner diameter slightly larger than the outer diameter of the rotating body 61, and is fixed to the bottom surface of the housing 46. The slip ring 60 is electrically connected to a DC power supply (not shown), and supplies a power from the DC power supply to the wiring 63 via the brush of the fixed body 62 and the metal ring of the rotating body 61. With this configuration, a potential can be applied from the DC power supply to the chuck electrode 21a without twisting the wiring 63. The slip ring 60 may have a structure other than the brush structure, for example, a contactless power supply structure, a mercury-free structure, a structure containing conductive liquid, or the like.

A cathode part (not shown) configured to sputter a plurality of targets is provided at the upper portion of the processing chamber 10 to face the placing table 20. The power supply connected to the cathode part may be at least one of a DC power supply and an RF power supply, or both the DC power supply and the RF power supply, but the present disclosure is not limited thereto. At least one of a DC voltage and an RF voltage may be applied to the cathode part from the DC power supply and/or the RF power supply.

The controller 80 is, for example, a computer, and includes a central processing unit (CPU), a random access memory (RAM), a read only memory (ROM), an auxiliary storage device, and the like. The CPU operates based on programs stored in the ROM or the auxiliary storage device, and controls the operation of the substrate processing apparatus 1. The controller 80 can control the substrate processing apparatus 1 using a wired or wireless communication device.

In the case of performing desired processing on the substrate W, as shown in FIGS. 1 and 2A, the controller 80 controls the lifting device 50 (the air cylinder 51) to separate the placing table 20 from the refrigeration medium 32, and controls the rotation device 40 (the rotation driving device 41) to rotate the placing table 20 on which the substrate W is placed. Further, the shield member 22 and the second reflecting member 72 rotate together with the placing table 20. Accordingly, the in-plane uniformity of the substrate processing (e.g., film formation or the like) of the substrate W can be improved.

Further, in the case of cooling the placing table 20 and the substrate W placed on the placing table 20, as shown in FIG. 2B, the controller 80 stops the rotation device 40 (the rotation driving device 41) to stop the rotation of the placing table 20, and controls the lifting device 50 (the air cylinder 51) to thermally connect the placing table 20 and the refrigeration medium 32. Accordingly, the substrate W mounted on the placing table 20 can be cooled.

### <Control of Refrigerator>

Next, the control of the refrigerator 31 will be described using FIG. 2. Hereinafter, a case in which the controller 80 controls the refrigerator 31 will be described, but the present disclosure is not limited thereto. The refrigerator 31 may have therein a controller (not shown) for controlling the refrigerator 31.

As shown in FIGS. 2A and 2B, a temperature sensor 81 is disposed at the head portion 32a of the refrigeration medium 32. A temperature sensor 82 is disposed at the placing table 20. The temperature sensor 81 is connected to the controller 80 to be able to communicate therewith in a wired manner. The temperature sensor 82 is connected to the controller 80 to be able to communicate therewith in a wireless manner. The temperature sensor 82 may be connected to the controller 80 via the slip ring 60.

As shown in FIG. 2A, when the placing table 20 rotates, the placing table 20 and the refrigeration medium 32 are separated. The controller 80 performs feedback control of the refrigerator 31 such that the temperature of the head portion 32a of the refrigeration medium 32 detected by the temperature sensor 81 becomes a predetermined target temperature. For example, a target temperature T₃₂ₐ of the head portion 32a is set to a value obtained by subtracting a predetermined temperature from a target temperature T₂₀ of the placing table 20 (e.g., T₃₂a=T₂₀−3[° C.]). The controller 80 performs feedback control of the refrigerator 31 based on the temperature T₈₁ detected by the temperature sensor 81 and the target temperature T₃₂ₐ of the head portion 32a. Further, the controller 80 monitors the temperature of the placing table 20 detected by the temperature sensor 82.

As shown in FIG. 2B, when the placing table 20 is cooled, the placing table 20 and the refrigeration medium 32 are in contact with each other. The controller 80 performs feedback control of the refrigerator 31 such that the temperature of the placing table 20 detected by the temperature sensor 82 becomes a predetermined target temperature. For example, the controller 80 sets the target temperature T₃₂ₐ of the head portion 32a based on the temperature T₈₂ detected by the temperature sensor 82 and the target temperature T₂₀ of the placing table 20. Next, the controller 80 performs feedback control of the refrigerator 31 based on the temperature T₈₁ detected by the temperature sensor 81 and the target temperature T₃₂ₐ of the head portion 32a.

In this manner, by providing the temperature sensor 81 close to the placing table 20 and at the head portion 32a of the refrigeration medium 32 that is in thermal contact with the placing table 20 during cooling, the refrigerator 31 can quickly respond to the temperature change in the head portion 32a. Accordingly, the temperature of the placing table 20 can be controlled accurately. Further, since the head portion 32a is not a part that rotates together with the placing table 20, the controller 80 and the temperature sensor 81 can be connected in a wired manner. Hence, the temperature detection can be performed accurately.

### <Structure for Supplying Power to Chuck Electrode>

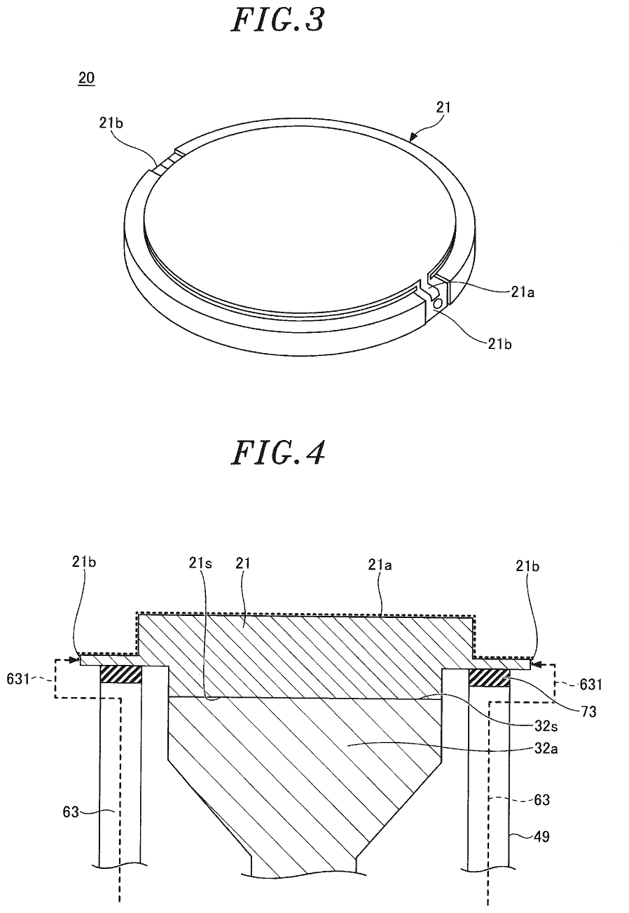

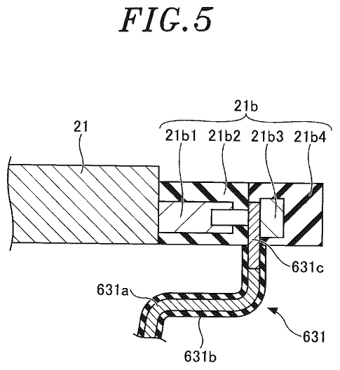

Next, a structure for supplying a power to the chuck electrode 21a will be described with reference to FIGS. 3 to 5. FIG. 3 is an example of a perspective view of the placing table 20. FIG. 4 is an example of a schematic diagram illustrating the structure for supplying a power to the chuck electrode 21a. FIG. 5 is an example of a schematic cross-sectional view of an electrode introducing part 21b.

As shown in FIG. 3, the placing table 20 has an electrode introducing part 21b that introduces a power to the chuck electrode 21a. Here, the electrode introducing part 21b is disposed on the side surface of the placing table 20.

As shown in FIG. 4, a power supply line 631 extending from the wiring 63 is connected to the electrode introducing part 21b. With this configuration, it is possible to ensure a wide contact area between the first contact surface 21s of the placing table 20 and the second contact surface 32s of the refrigeration medium 32 (the head portion 32a). In other words, in the contact area where the first contact surface 21s and the second contact surface 32s are in contact with each other, the contact can be made over the entire surface without a portion where the first contact surface 21s and the second contact surface 32s are not in contact. Accordingly, the first contact surface 21s of the placing table 20 and the second contact surface 32s of the refrigeration medium 32 can be brought into thermal contact with each other, thereby improving the cooling performance during cooling of the placing table 20.

As shown in FIG. 5, the power supply line 631 has a conductive wire 631a, an insulating tube 631b that covers the conductive wire 631a, and a terminal portion 631c. The conductive wire 631a is made of a metal material such as SUS or the like. The insulating tube 631b is made of an insulating material such as PTFE or the like. The terminal portion 631c is disposed at one end of the conductive wire 631a, and is electrically connected to the conductive wire 631a. The other end of the power supply line 631 is connected to the wiring 63, and is connected to a power supply (not shown) via the slip ring 60.

The electrode introducing part 21b has a conductive portion 21b1, an insulating cover 21b2, a fastening bolt 21b3, and an insulating cover 21b4. The conductive portion 21b1 is made of a conductive material, and is electrically connected to the chuck electrode 21a (see FIG. 4). The conductive portion 21b1 has a recess having a female thread coupled to the fastening bolt 21b3. The insulating cover 21b2 is made of an insulating material such as PEEK (polyetheretherketone) or the like, and covers the conductive portion 21b1. The insulating cover 21b2 has a hole through which the fastening bolt 21b3 is inserted. The fastening bolt 21b3 is made of a conductive material, and is electrically connected to the terminal portion 631c of the power supply line 631. Accordingly, the conductive wire 631a of the power supply line 631 is electrically connected to the chuck electrode 21a via the terminal portion 631c, the fastening bolt 21b3, and the conductive portion 21b1. The insulating cover 21b4 is made of an insulating material such as PEEK or the like, and covers the terminal portion 631c and the fastening bolt 21b3.

In this manner, the conductive member (the conductive portion 21b1 and the fastening bolt 21b3) of the electrode introducing part 21b and the terminal portion 631c of the power supply line 631 are covered with the insulating member (the insulating cover 21b2 and the insulating cover 21b4). Accordingly, it is possible to prevents abnormal discharge from occurring in the conductive member of the electrode introducing part 21b when plasma is generated in the inner space 10S and the substrate W is subjected to plasma processing.

While the substrate processing apparatus 1 has been described above, the present disclosure is not limited to the above-described embodiment, and various changes and modifications may be made.

1. A substrate processing apparatus comprising:
a processing chamber;
a placing table disposed in the processing chamber and having a first contact surface, the placing table being configured to be rotatable;
a freezing device having a second contact surface and configured to be raised and lowered;
a rotation device configured to rotate the placing table; and
a lifting device configured to raise and lower the freezing device to thermally connect or separate the second contact surface and the first contact surface,
wherein the freezing device includes:
a refrigerator;
a cold link having one end thermally connected to the refrigerator and the other end having the second contact surface,
wherein a volume of the cold link is greater than a volume of the placing table.

2. The substrate processing apparatus of claim 1, wherein the cold link has a head portion having the second contact surface and a shaft portion that thermally connects the head portion and the refrigerator,
wherein a volume of the head portion of the cold link is greater than a volume of the shaft portion of the cold link.

3. The substrate processing apparatus of claim 1, wherein the cold link has a head portion having the second contact surface and a shaft portion that thermally connects the head portion and the refrigerator,
wherein a volume of the head portion of the cold link is greater than a volume of the placing table.

4. The substrate processing apparatus of claim 1, wherein the first contact surface and the second contact surface are flat surfaces.

5. The substrate processing apparatus of claim 4, wherein in the contact area where the first contact surface and the second contact surface are in contact with each other, the contact is made over the entire surface without a portion where the first contact surface and the second contact surface are not in contact.

6. The substrate processing apparatus of claim 4, wherein the placing table includes an electrostatic chuck having a chuck electrode and an electrode introducing part configured to introduce a power to the chuck electrode,
wherein the electrode introducing part is disposed on a side surface of the placing table.

7. The substrate processing apparatus of claim 6, wherein the substrate processing apparatus is a substrate processing apparatus that generates plasma in the processing chamber to process the substrate,
wherein a conductive member of the electrode introducing part is covered with an insulating member.

8. The substrate processing apparatus of claim 1, further comprising:
a reflecting member configured to reflect radiant heat incident on the cold link.
